(19) United States
(12) Patent Application Publication
(10) Pub. No.: US 2025/0354261 A1
(43) Pub. Date: Nov. 20, 2025

(54) METHOD FOR MANUFACTURING NITRIDE SEMICONDUCTOR SUBSTRATE

(71) Applicant: SUMITOMO ELECTRIC INDUSTRIES, LTD., Osaka (JP)

(72) Inventor: Ryosuke UGAJI, Osaka (JP)

(21) Appl. No.: 19/203,570

(22) Filed: May 9, 2025

(30) Foreign Application Priority Data
May 20, 2024 (JP) 2024-082138

(51) Int. Cl. C23C 16/455; C23C 16/30; H01L 21/02

(52) U.S. Cl. CPC C23C 16/45523; C23C 16/303; H01L 21/02378; H01L 21/0254; H01L 21/0262

(57) ABSTRACT

A method for manufacturing a nitride semiconductor substrate includes forming a first nitride semiconductor layer including aluminum, on a substrate that is at a first temperature; changing a temperature of the substrate and the first nitride semiconductor layer to a second temperature, the second temperature being higher than the first temperature; and forming a second nitride semiconductor layer including aluminum, on the first nitride semiconductor layer that is at the second temperature. In the forming of the first nitride semiconductor layer, a first V/III ratio to a supply amount of a Group V element to a supply amount of a Group III element is higher than a second V/III ratio to a supply amount of the Group V element to a supply amount of the Group III element in the forming of the second nitride semiconductor layer.

### CROSS-REFERENCE TO RELATED APPLICATION

This application claims priority under 35 U.S.C. § 119 to Japanese Patent Application No. 2024-082138, filed May 20, 2024, the contents of which are incorporated herein by reference.

### BACKGROUND

### 1. Technical Field

The present disclosure relates to a method for manufacturing a nitride semiconductor substrate.

### 2. Description of the Related Art

Nitride semiconductor substrates are used in semiconductor devices such as gallium nitride (GaN)-based high electron mobility transistors (HEMTs). A nitride semiconductor substrate includes a substrate such as a silicon carbide (SiC) substrate, and includes a nucleation layer such as an aluminum nitride (AlN) layer. A semiconductor layer such as a channel layer is formed on the nucleation layer.

### RELATED-ART DOCUMENT

Patent Document 1: Japanese Unexamined Patent Application Publication No. 2021-073702
Patent Document 2: Japanese Unexamined Patent Application Publication No. 2020-530939
Patent Document 3: Japanese Unexamined Patent Application Publication No. 2018-206928

### SUMMARY

A method for manufacturing a nitride semiconductor substrate includes forming a first nitride semiconductor layer including aluminum, on a substrate that is at a first temperature; changing a temperature of the substrate and the first nitride semiconductor layer to a second temperature, the second temperature being higher than the first temperature; and forming a second nitride semiconductor layer including aluminum, on the first nitride semiconductor layer that is at the second temperature. In the forming of the first nitride semiconductor layer, a first V/III ratio to a supply amount of a Group V element to a supply amount of a Group III element is higher than a second V/III ratio to a supply amount of the Group V element to a supply amount of the Group III element in the forming of the second nitride semiconductor layer.

### BRIEF DESCRIPTION OF THE DRAWINGS

FIG. 1 is a diagram showing aspects of changes in temperature and flow rate of a source gas in a method for manufacturing a nitride semiconductor substrate according to a first embodiment.

FIG. 2 is a cross-sectional view (part 1) showing the method for manufacturing the nitride semiconductor substrate according to the first embodiment.

FIG. 3 is a cross-sectional view (part 2) showing the method for manufacturing the nitride semiconductor substrate according to the first embodiment.

FIG. 4 is a diagram showing aspects of changes in temperature and flow rate of the source material gas in the method for manufacturing the nitride semiconductor substrate according to a second embodiment.

FIG. 5 is a diagram showing aspects of changes in temperature and flow rate of the source material gas in the method for manufacturing the nitride semiconductor substrate according to a third embodiment.

FIG. 6 is a cross-sectional view showing a HEMT manufactured using the nitride semiconductor substrate.

### DETAILED DESCRIPTION

Good crystallinity is desired in a semiconductor layer from the viewpoint of electrical characteristics such as electron mobility, and in a conventional semiconductor device, good crystallinity is obtained on the upper surface of the semiconductor device by forming the semiconductor layer with an increased thickness. On the other hand, in recent years, an amount of heat generated is increasing with the improvement in an operating speed of the semiconductor device such as a HEMT. In view of the above situation, in order to improve heat dissipation of the semiconductor device, there is an increasing demand to improve the crystallinity of a nitride semiconductor substrate so that good crystallinity can be obtained even when the semiconductor layer is formed thinly.

An object of the present disclosure is to provide a method for manufacturing a nitride semiconductor substrate capable of improving the crystallinity.

### Description of Embodiments of the Present Disclosure

Embodiments of the present disclosure will be first listed and described.

(1) A method for manufacturing a nitride semiconductor substrate includes forming a first nitride semiconductor layer including aluminum, on a substrate that is at a first temperature; changing a temperature of the substrate and the first nitride semiconductor layer to a second temperature, the second temperature being higher than the first temperature; and forming a second nitride semiconductor layer including aluminum, on the first nitride semiconductor layer that is at the second temperature, the second nitride semiconductor. In the forming of the first nitride semiconductor layer, a first V/III ratio to a supply amount of a Group V element to a supply amount of a Group III element is higher than a second V/III ratio to a supply amount of the Group V element to a supply amount of the Group III element in the forming of the second nitride semiconductor layer.

When a first V/III ratio is higher than a second V/III ratio, and a second temperature is higher than a first temperature, a first nitride semiconductor layer can be formed more densely than the second nitride semiconductor layer. Also, atom migration is more likely to occur when forming the second nitride semiconductor layer than when forming the first nitride semiconductor layer. In addition, when the first temperature is changed to the second temperature, atoms constituting the first nitride semiconductor layer thermally diffuse, and flatness of the upper surface of the first nitride semiconductor layer is improved. In this case, grooves caused by steps included in a substrate may locally occur in the first nitride semiconductor layer. However, even if the grooves occur, atom migration is likely to occur when forming the second nitride semiconductor layer, and the grooves are filled with the second nitride semiconductor layer. As a result, good crystallinity is obtained in the second nitride semiconductor layer.

[2] In [1], a first nitride semiconductor layer and a second nitride semiconductor layer may be aluminum nitride layers. In this case, the first nitride semiconductor layer and the second nitride semiconductor layer are easily formed with high stability.

[3] In [1] or [2], a first temperature may be higher than or equal to 600° C. and less than 1,000° C., and a second temperature may be higher than or equal to 1,000° C. and less than or equal to 1,200° C. When the first temperature is 600° C. or higher, a first nitride semiconductor layer can be formed easily, and when the first temperature is less than 1,000° C., atom migration is unlikely to occur when forming the first nitride semiconductor layer. When the second temperature is 1,000° C. or higher, atom migration is likely to occur when forming the second nitride semiconductor layer, and when a second temperature is 1,200° C. or less, the first nitride semiconductor layer and the second nitride semiconductor layer are easily formed in the same furnace without exposure to atmosphere.

[4] In any one of [1] to [3], a difference between a second temperature and a first temperature may be 100° C. or higher. In this case, a first nitride semiconductor layer is easily formed with high density, and a second nitride semiconductor layer is easily formed with good crystallinity.

[5] In any one of [1] to [4], first pressure in a furnace in forming a first nitride semiconductor layer may be higher than second pressure in the furnace in forming a second nitride semiconductor layer. In this case, the first nitride semiconductor layer is easily formed with high density, and the second nitride semiconductor layer is easily formed with good crystallinity.

[6] In any one of [1] to [5], a total thickness of a first nitride semiconductor layer and a second nitride semiconductor layer may be 50 nm or less. When the total thickness is 50 nm or less, heat is easily transferred from a semiconductor layer formed on the second nitride semiconductor layer, to a substrate.

[7] In any one of [1] to [6], a second nitride semiconductor layer may be thicker than a first nitride semiconductor layer. In this case, grooves formed in the first nitride semiconductor layer are easily filled with the second nitride semiconductor layer.

[8] In any one of [1] to [7], a first nitride semiconductor layer may have a thickness of greater than or equal to 3 nm and less than or equal to 20 nm, and a second nitride semiconductor layer may have a thickness of greater than or equal to 5 nm and less than or equal to 30 nm. When the thickness of the first nitride semiconductor layer is 20 nm or less, and the thickness of the second nitride semiconductor layer is 30 nm or less, heat is easily transferred from a semiconductor layer formed on the second nitride semiconductor layer to a substrate. On the other hand, it is difficult to form a first nitride semiconductor layer having a thickness of less than 3 nm. If the thickness of the second nitride semiconductor layer is less than 5 nm, it might be difficult to fill grooves formed in the first nitride semiconductor layer.

[9] In any one of [1] to [8], changing of a temperature of a substrate and a first nitride semiconductor layer to a second temperature to a second temperature may include changing the temperature of the substrate and the first nitride semiconductor layer to a third temperature that is higher than the second temperature, and may include changing the temperature of the substrate and the first nitride semiconductor layer from the third temperature to the second temperature. In this case, thermal diffusion of atoms constituting the first nitride semiconductor layer is further activated at the third temperature, and flatness of an upper surface of the first nitride semiconductor layer is further improved.

[10] In [9], a third temperature may be higher than or equal to 1,100° C. and less than or equal to 1,300° C. When the third temperature is 1,100° C. or higher, thermal diffusion of atoms constituting a first nitride semiconductor layer is easily activated, and when the third temperature is 1,300° C. or less, the first nitride semiconductor layer and a second nitride semiconductor layer are easily formed in the same furnace without exposure to atmosphere.

[11] In any one of [1] to [10], a method for manufacturing a nitride semiconductor substrate may further include, after changing a temperature of a substrate and a first nitride semiconductor layer to a second temperature, and before forming a second nitride semiconductor layer, maintaining the temperature of the substrate and the first nitride semiconductor layer at the second temperature without forming a second nitride semiconductor layer. In this case, atoms are thermally diffused while the temperature is maintained at the second temperature, and flatness of an upper surface of the first nitride semiconductor layer is further improved.

[12] In any one of [1] to [11], a substrate may be a silicon carbide substrate. In this case, a first nitride semiconductor layer and a second nitride semiconductor layer are easily formed with good crystallinity.

### Details of Embodiments of the Present Disclosure

Embodiments of the present disclosure will be described in detail below, but the present disclosure is not limited to the embodiments. In this description and drawings, duplicate description for components having substantially the same functional configuration may be omitted by denoting the same reference numerals.

### First Embodiment

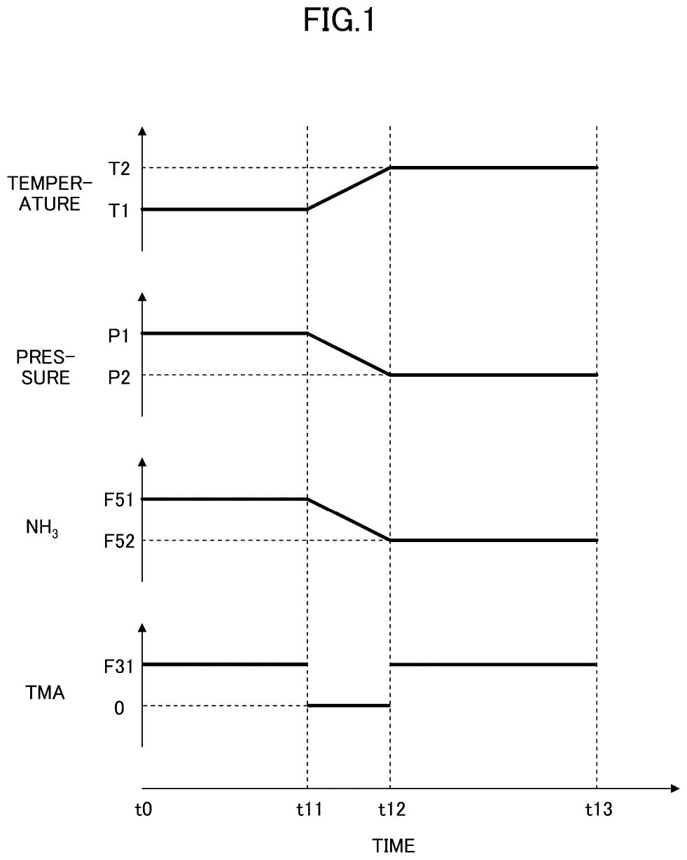

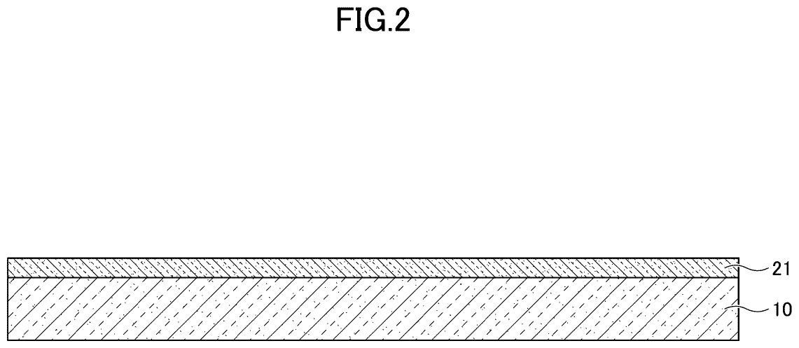

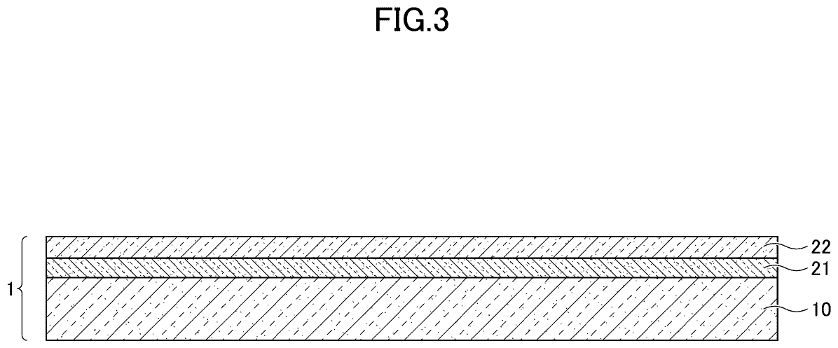

A first embodiment will be described hereinafter. The first embodiment relates to a method for manufacturing a nitride semiconductor substrate. FIG. 1 is a diagram showing aspects of changes in temperature and flow rate of a source gas in the method for manufacturing the nitride semiconductor substrate according to the first embodiment. FIGS. 2 and 3 are cross-sectional views showing the method for manufacturing the nitride semiconductor substrate according to the first embodiment.

In the first embodiment, as shown in FIG. 2, a first aluminum nitride (AlN) layer 21 is formed on a substrate 10 during a period from time t0 to time t11. The substrate 10 is, for example, a silicon carbide (SiC) substrate. When the substrate 10 is the SiC substrate, the first AlN layer 21 is formed on a silicon (Si) polar surface of the substrate 10. The first AlN layer 21 can be formed by, for example, metal organic chemical vapor deposition (MOCVD). When the first AlN layer 21 is formed, the temperature of the substrate 10 is set as a first temperature T1, and pressure in a furnace is set as first pressure P1, as shown in FIG. 1. For example, the first temperature T1 is higher than or equal to 600° C. and less than 1,000° C., and the first pressure P1 is higher than or equal to 10 kPa and less than or equal to 40 kPa. Trimethylaluminum (TMA) is used as a source material for aluminum (Al), which is a Group III element, and ammonia (NH₃) is used as a source material for nitrogen (N), which is a Group V element. For example, when the first AlN layer 21 is formed, a flow rate F31 of the TMA and a flow rate F51 of the NH₃ are adjusted according to the size of the furnace, and thus a first V/III ratio of a supply amount (mol) of the N to a supply amount (mol) of the Al is higher than or equal to 5,000 and less than or equal to 20,000. The first AlN layer 21 is an example of a first nitride semiconductor layer.

The formation of the first AlN layer 21 is completed by stopping the supplying of the TMA to the furnace at the time t11. The thickness of the first AlN layer 21 is, for example, greater than or equal to 3 nm and less than or equal to 20 nm. Next, during a period from the time t11 to time t12, exclusive of the time t12, the temperature of the substrate 10 and the first AlN layer 21 is changed from the first temperature T1 to a second temperature T2. The second temperature T2 is higher than the first temperature T1. During the period from the time t11 to the time t12, exclusive of the time t12, the pressure in the furnace is decreased from the first pressure P1 to second pressure P2, and the flow rate of the NH₃ is decreased from the flow rate F51 to a flow rate F52. For example, the second temperature T2 is higher than or equal to 1,000° C. and less than or equal to 1,200° C., and the second pressure P2 is greater than or equal to 3 kPa and less than or equal to 30 kPa. Also, the supplying of the TMA is kept stopped. In such a situation, the AlN layer is not formed during the period from the time t11 to the time t12, exclusive of the time t12.

Next, at the time t12, the supplying of the TMA to the furnace is resumed to start the formation of the second AlN layer 22. At time t13, the supplying of the TMA to the furnace is stopped to complete the formation of the second AlN layer 22. That is, as shown in FIG. 3, the second AlN layer 22 is formed on the first AlN layer 21 during a period from the time t12 to the time t13. The thickness of the second AlN layer 22 is, for example, greater than or equal to 5 nm and less than or equal to 30 nm. The second AlN layer 22 can be formed by, for example, MOCVD. When the second AlN layer 22 is formed, the temperature of the substrate 10 and the first AlN layer 21 is set to the second temperature T2, and the pressure in the furnace is set to the second pressure P2. For example, when the second AlN layer 22 is formed, the flow rate F31 of the TMA and the flow rate F52 of the NH₃ are adjusted according to the size of the furnace, and a second V/III ratio of a supply amount (mol) of the N to a supply amount (mol) of the Al is set to 2,000 or less. A lower second V/III ratio is preferably obtained from the viewpoint of migration. For example, the second V/III ratio may be 50 or less, and may be 1 or less. The first V/III ratio is higher than the second V/III ratio. The second AlN layer 22 is an example of a second nitride semiconductor layer. A value of the flow rate F31 of TMA obtained when forming the second AlN layer 22 may be the same as a value of the flow rate F31 of TMA obtained when forming the first AlN layer 21.

In this arrangement, the nitride semiconductor substrate 1 including the substrate 10, the first AlN layer 21, and the second AlN layer 22 can be manufactured.

In the first embodiment, the first V/III ratio is higher than the second V/III ratio, the first AlN layer 21 is formed at the first temperature T1 of, for example, higher than or equal to 600° C. and less than 1,000° C., and the second AlN layer 22 is formed at the second temperature T2 of, for example, higher than or equal to 1,000° C. and less than or equal to 1,200° C. In this arrangement, the first AlN layer 21 can be formed more densely than the second AlN layer 22, and atomic migration is more likely to occur when forming the second AlN layer 22 than when forming the first AlN layer 21. In addition, when the temperature changes from the first temperature T1 to the second temperature T2, atoms constituting the first AlN layer 21 are thermally diffused, and as a result, flatness of the upper surface of the first AlN layer 21 is improved. In this case, grooves caused by steps included in the substrate 10 may locally occur in the first AlN layer 21. However, even if the grooves occur, atom migration is likely to occur when forming the second AlN layer 22, and the grooves can be filled with the second AlN layer 22. As a result, good crystallinity is obtained in the second AlN layer 22, and good flatness is obtained at the upper surface of the second AlN layer 22. In this arrangement, by use of the second AlN layer 22 as a nucleation layer, a semiconductor layer having good crystallinity can be formed on the nitride semiconductor substrate 1, even when the semiconductor layer is thin. By making the semiconductor layer thinner, heat dissipation of a semiconductor device, such as a HEMT that includes the semiconductor layer, can be improved.

When the first temperature T1 is 600° C. or higher, the first AlN layer 21 is formed easily. When the first temperature T1 is less than 1,000° C., atom migration is unlikely to occur when forming the first AlN layer 21, and as a result, the first AlN layer 21 is easily formed with high density. When the second temperature T2 is 1,000° C. or higher, atom migration is likely to occur when forming the second AlN layer 22, and as a result, grooves formed in the first AlN layer 21 are easily filled with the second AlN layer 22. When the second temperature T2 is 1,200° C. or less, the first AlN layer 21 and the second AlN layer 22 are easily formed in the same furnace without exposure to atmosphere. The first temperature T1 may be higher than or equal to 650° C. and less than or equal to 850° C. The second temperature T2 may be higher than or equal to 1,050° C. and less than or equal to 1,150° C.

When the difference between the second temperature T2 and the first temperature T1 is 100° C. or higher, the first AlN layer 21 is easily formed with high density, and the second AlN layer 22 is formed with good crystallinity. The difference between the second temperature T2 and the first temperature T1 may be 250° C. or higher, and may be 300° C. or higher.

When the first pressure P1 is greater than the second pressure P2, the first AlN layer 21 is easily formed with high density, and the second AlN layer 22 is easily formed with good crystallinity.

When a total thickness of the first AlN layer 21 and the second AlN layer 22 is 50 nm or less, heat is easily transferred from the semiconductor layer formed on the second AlN layer 22 to the substrate 10. The total thickness may be 40 nm or less, and may be 30 nm or less. When the second AlN layer 22 is thicker than the first AlN layer 21, grooves formed in the first AlN layer 21 are easily filled with the second AlN layer 22.

For example, the thickness of the first AlN layer 21 is greater than or equal to 3 nm and less than or equal to 20 nm, and the thickness of the second AlN layer 22 is greater than or equal to 5 nm and less than or equal to 30 nm. When the thickness of the first AlN layer 21 is 20 nm or less, and the thickness of the second AlN layer 22 is 30 nm or less, heat is easily transferred from the semiconductor layer formed on the second AlN layer 22 to the substrate 10. On the other hand, it is difficult to form the first AlN layer 21 that has a thickness of less than 3 nm. If the thickness of the second AlN layer 22 is less than 5 nm, it might be difficult to fill grooves formed in the first AlN layer 21.

When the substrate 10 is a silicon carbide substrate having high thermal conductivity, heat dissipation is easily improved by forming the first AlN layer 21 and the second AlN layer 22 to be thin on the substrate.

### Second Embodiment

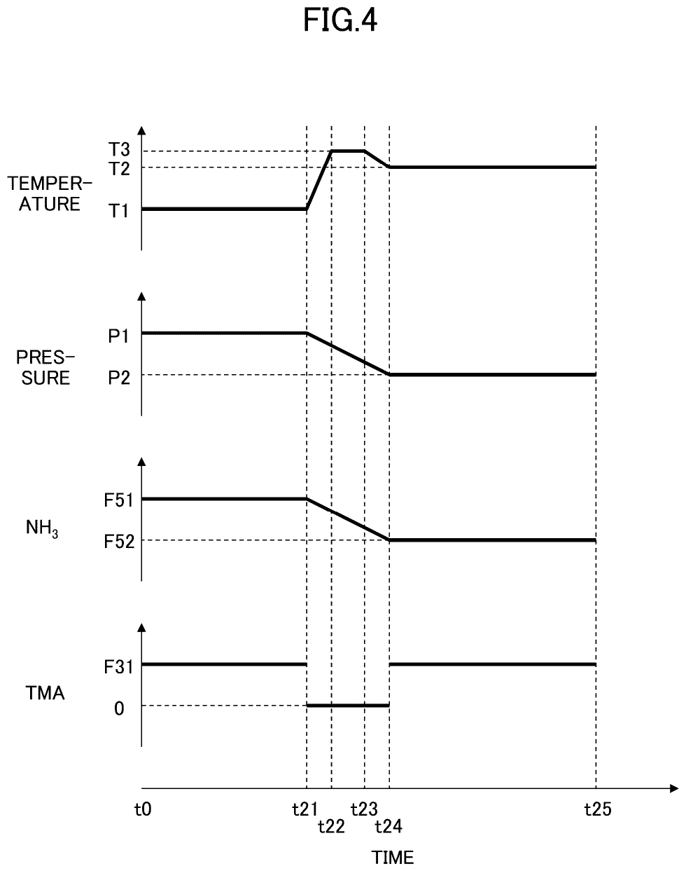

Hereinafter, a second embodiment will be described. The second embodiment differs from the first embodiment mainly in aspects of temperature changes after the formation of the first AlN layer 21 and before the formation of the second AlN layer 22. FIG. 4 is a diagram showing the aspects of changes in temperature and flow rate of the source gas in the method for manufacturing the nitride semiconductor substrate according to the second embodiment.

In the second embodiment, the first AlN layer 21 is formed on the substrate 10 (see FIG. 2) during a period from time t0 to time t21, exclusive of the time t21. The first AlN layer 21 is formed under the same conditions as in the first embodiment.

The formation of the first AlN layer 21 is completed by stopping the supplying of the TMA to the furnace at the time t21. Next, the temperature of the substrate 10 and the first AlN layer 21 is changed from the first temperature T1 to a third temperature T3 during a period from the time t21 to time t22, exclusive of the time t22. The third temperature T3 is higher than the second temperature T2. For example, the third temperature T3 is higher than or equal to 1,100° C. and less than or equal to 1,300° C. Next, the temperature of the substrate 10 and the first AlN layer 21 is maintained at the third temperature T3 during a period from the time t22 to time t23, exclusive of the time t23. The period from the time t22 to the time t23, exclusive of the time t23, is, for example, from 1 minute to 60 minutes. Next, during the period from the time t23 to time t24, exclusive of the time t24, the temperature of the substrate 10 and the first AlN layer 21 is changed from the third temperature T3 to the second temperature T2. During a period from the time t21 to the time t24, exclusive of the time t24, the pressure in the furnace is decreased from the first pressure P1 to the second pressure P2, and the flow rate of the NH₃ is decreased from the flow rate F51 to the flow rate F52. Also, the supplying of the TMA is kept stopped. In this arrangement, the AlN layer is not formed during the period from the time t21 to the time t24, exclusive of the time t24.

Next, the supplying of the TMA to the furnace is resumed at the time t24 to start the formation of the second AlN layer 22. The supplying of the TMA to the furnace is stopped at time t25 to complete the formation of the second AlN layer 22. That is, the second AlN layer 22 is formed on the first AlN layer 21 (see FIG. 3) during the period from the time t24 to the time t25. The second AlN layer 22 is formed under the same conditions as in the first embodiment.

With this approach, the nitride semiconductor substrate 1 can be manufactured.

In the second embodiment, after the formation of the first AlN layer 21 and before the formation of the second AlN layer 22, the temperature of the first AlN layer 21 is set to the third temperature T3, which is higher than the second temperature T2. As a result, thermal diffusion of Al atoms and N atoms that constitute the first AlN layer 21 is further activated, and flatness of the upper surface of the first AlN layer 21 is further improved. Therefore, good crystallinity is obtained from the second AlN layer 22, and good flatness is obtained from the upper surface of the second AlN layer 22.

When the third temperature T3 is 1,100° C. or higher, thermal diffusion of atoms that constitute the first AlN layer 21 is likely to be activated, and when the third temperature T3 is 1,300° C. or less, the first AlN layer 21 and the second AlN layer 22 are easily formed in the same furnace without exposure to atmosphere. The third temperature T3 may be higher than or equal to 1,150° C. and less than or equal to 1,250° C.

### Third Embodiment

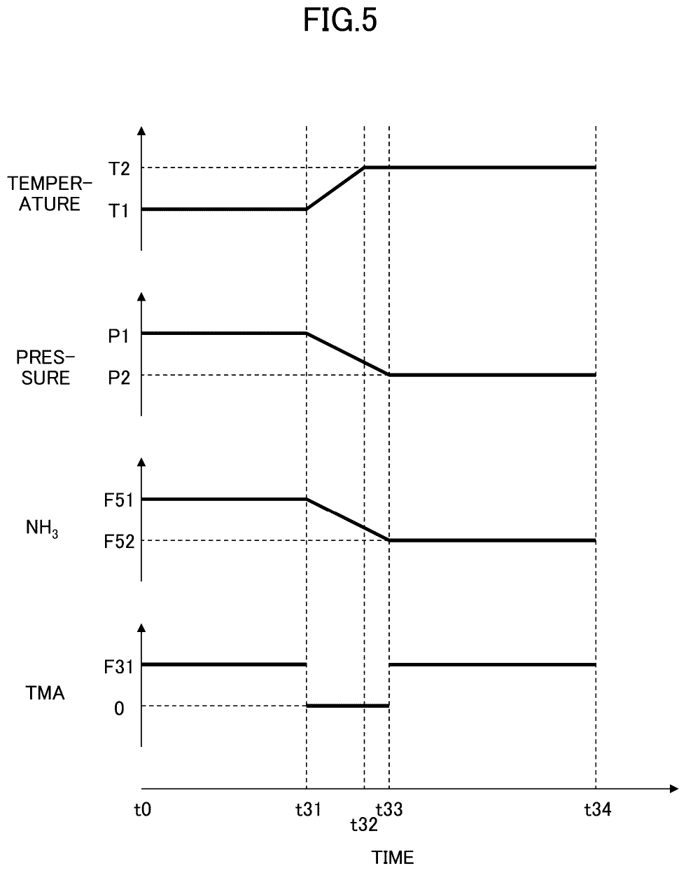

Hereinafter, a third embodiment will be described. The third embodiment differs from the first embodiment mainly in the aspects of temperature changes after the formation of the first AlN layer 21 and before the formation of the second AlN layer 22. FIG. 5 is a diagram showing the aspects of changes in temperature and flow rate of the source gas in the method for manufacturing the nitride semiconductor substrate according to the third embodiment.

In the third embodiment, the first AlN layer 21 is formed on the substrate 10 (see FIG. 2) during a period from time t0 to time t31, exclusive of the time t31. The first AlN layer 21 is formed under the same conditions as in the first embodiment.

The formation of the first AlN layer 21 is completed by stopping the supply of the TMA to the furnace at the time t31. Next, the temperature of the substrate 10 and the first AlN layer 21 is changed from the first temperature T1 to the second temperature T2 during a period from the time t31 to time t32, exclusive of the time t32. Next, the temperature of the substrate 10 and the first AlN layer 21 is maintained at the second temperature T2 during a period from the time t32 to time t33, exclusive of the time t33. The period from the time t32 to the time t33, exclusive of the time t33, is, for example, from 1 minute to 60 minutes. During the period from the time t31 to the time t33, exclusive of the time t33, the pressure in the furnace is decreased from the first pressure P1 to the second pressure P2, and the flow rate of the NH₃ is decreased from the flow rate F51 to the flow rate F52. Also, the supplying of the TMA is kept stopped. In this arrangement, the AlN layer is not formed in the period from the time t31 to the time t33, exclusive of t33.

Next, the supplying of the TMA to the furnace is resumed at the time t33 to start the formation of the second AlN layer 22. The supplying of the TMA to the furnace is stopped at time t34 to complete the formation of the second AlN layer 22. That is, the second AlN layer 22 is formed on the first AlN layer 21 (see FIG. 3) during a period from the time t33 to the time t34. The second AlN layer 22 is formed under the same conditions as in the second embodiment.

With this approach, the nitride semiconductor substrate 1 can be manufactured.

In the third embodiment, the temperature of the first AlN layer 21 is maintained at the second temperature T2, after the formation of the first AlN layer 21 and before the formation of the second AlN layer 22, that is, during the period from the time t32 to the time t33, exclusive of the time t33. As a result, a time period of thermal diffusion of Al atoms and N atoms that constitute the first AlN layer 21 is increased, and flatness of the upper surface of the first AlN layer 21 is further improved. Therefore, good crystallinity is obtained from the second AlN layer 22, and good flatness is obtained from the upper surface of the second AlN layer 22.

### (HEMT)

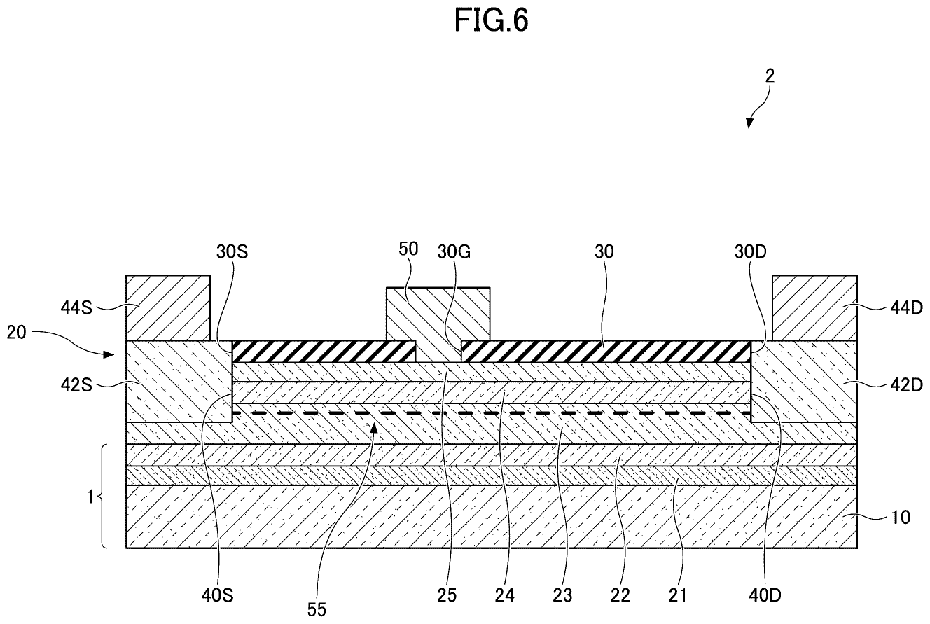

Hereinafter, an example of a HEMT manufactured using the nitride semiconductor substrate 1 will be described. FIG. 6 is a cross-sectional view showing the HEMT manufactured using the nitride semiconductor substrate 1.

As shown in FIG. 6, a HEMT 2 manufactured using the nitride semiconductor substrate 1 includes the substrate 10, a semiconductor laminate 20, an insulating film 30, a gate electrode 50, a source electrode 44S, and a drain electrode 44D.

The semiconductor laminate 20 includes the first AlN layer 21, the second AlN layer 22, a channel layer 23, a barrier layer 24, a cap layer 25, a regrowth layer 42S, and a regrowth layer 42D.

The channel layer 23 is disposed on the second AlN layer 22. The channel layer 23 is, for example, an undoped gallium nitride (GaN) layer. The barrier layer 24 is disposed on the channel layer 23. The barrier layer 24 is, for example, an n-type AlGaN layer. Two dimensional electron gas (2DEG) 55 exists in proximity to the upper surface of the channel layer 23. The cap layer 25 is disposed on the barrier layer 24. The cap layer 25 is, for example, an n-type GaN layer.

A recess 40S for a source and a recess 40D for a drain are formed in the cap layer 25, the barrier layer 24 and a portion of the channel layer 23. The recesses 40S and 40D penetrate through the cap layer 25 and the barrier layer 24, and enter into the channel layer 23. The channel layer 23 is exposed through the recesses 40S and 40D.

The insulating film 30 is disposed on the cap layer 25. The insulating film 30 is, for example, a silicon nitride (SiN) film. An opening 30S for the source and an opening 30D for the drain are formed in the insulating film 30. The opening 30S is connected to the recess 40S, and the opening 30D is connected to the recess 40D.

The regrowth layer 42S is disposed on the channel layer 23 in the recess 40S and opening 30S. The regrowth layer 42D is disposed on the channel layer 23 in the recess 40D and the opening 30D. The regrowth layers 42S and 42D are, for example, n-type GaN layers. The electrical resistance of the regrowth layers 42S and 42D is lower than that of the channel layer 23.

A source electrode 44S is disposed on the regrowth layer 42S, and the drain electrode 44D is disposed on the regrowth layer 42D. The source electrode 44S is in direct contact with the regrowth layer 42S, and the drain electrode 44D is in direct contact with the regrowth layer 42D. The source electrode 44S is in ohmic contact with the regrowth layer 42S, and the drain electrode 44D is in ohmic contact with the regrowth layer 42D.

An opening 30G for a gate is formed in the insulating film 30. The opening 30G is located between the opening 30S and the opening 30D. The gate electrode 50 is provided on the insulating film 30, and is in Schottky contact with the semiconductor laminate 20 through the opening 30G.

In such a HEMT 2, the channel layer 23 with good crystallinity and having a decreased thickness, the barrier layer 24, and the cap layer 25 can be formed on and above the second AlN layer 22. For example, when the channel layer 23 is a GaN layer with a mirror index of [002] on its upper surface and having a thickness of 200 nm, the half-width of the X-ray rocking curve (XRC) on the upper surface of the channel layer 23 can be 200 arcsec or less.

In the present disclosure, the first nitride semiconductor layer and the second nitride semiconductor layer are not limited to aluminum nitride layers. A composition of the first nitride semiconductor layer may be expressed as In_{X1}Al_{Y1}Ga_{1-X1-Y1}N (0≤X1<1, 0<Y1≤1, and 0<X1+Y1≤1). A composition of the second nitride semiconductor layer may be expressed as In_{X2}Al_{Y2}Ga_{1-X2-Y2}N (0≤X2<1, 0<Y2≤1, and 0<X2+Y2≤1). However, when the first nitride semiconductor layer and the second nitride semiconductor layer are the aluminum nitride layers, the first nitride semiconductor layer and the second nitride semiconductor layer are easily formed with stability.

Hereinafter, an experiment performed by the inventor of this application will be described. In this experiment, four samples, Nos. 1, 2, 3, and 4, are prepared.

In each of Sample Nos. 1 and 2, as described in the second embodiment, the first AlN layer 21 and the second AlN layer 22 are formed on and above the SiC substrate 10, and a GaN layer is formed following the second AlN layer 22. The thickness of the first AlN layer 21 is 10 nm, and the thickness of the second AlN layer 22 is 10 nm. In Sample No. 1, the thickness of the GaN layer is 200 nm, and in Sample No. 2, the thickness of the GaN layer is 400 nm. The first temperature T1 is 700° C., the third temperature T3 is 1,100° C., and the second temperature T2 is 1,000° C.

In each of Sample Nos. 3 and 4, an AlN layer having a thickness of 20 nm is formed on the SiC substrate at a substrate temperature of 1,100° C., and a GaN layer is formed following the AlN layer. In Sample No. 3, the GaN layer has a thickness of 200 nm, and in Sample No. 4, the GaN layer has a thickness of 400 nm.

Then, for each of Sample Nos. 1, 2, 3, and 4, the full width at half maximum (FWHM) of the X-ray rocking curve on the upper surface of the GaN layer is measured. The mirror index of the upper surface of the GaN layer is [002]. The results are shown in Table 1.

TABLE 1

| | THICKNESS OF | FULL WIDTH AT |
|---|---|---|
| SAMPLE | GaN LAYER (nm) | HALF MAXIMUM (arcsec) |
| No. 1 | 200 | 192 |
| No. 2 | 400 | 207 |
| No. 3 | 200 | 550 |
| No. 4 | 400 | 407 |

As shown in Table 1, in Sample No. 2, the full width at half maximum is 207 arcsec, and in Sample No. 4, the full width at half maximum is 407 arcsec. As a result, good crystallinity is obtained. However, because the thickness of the GaN layer is 400 nm, heat dissipation may be insufficient. In Sample No. 3, the thickness of the GaN layer is 200 nm, and thus heat dissipation is increased compared to the case of Sample Nos. 2 and 4. However, in Sample No. 3, the full width at half maximum is 550 arcsec, and as a result, crystallinity is reduced. On the other hand, in Sample No. 1, the thickness of the GaN layer is 200 nm and the full width at half maximum is 192 arcsec. As a result, in Sample No. 1, good crystallinity is obtained in the GaN layer while providing high heat dissipation.

Although the above embodiments have been described in detail, the present disclosure is not limited to specific embodiment(s), and various modifications and changes can be made within the scope of the present disclosure.

In the present disclosure, crystallinity of a nitride semiconductor substrate can be improved.

What is claimed is:

1. A method for manufacturing a nitride semiconductor substrate, comprising:
forming a first nitride semiconductor layer including aluminum, on a substrate that is at a first temperature;
changing a temperature of the substrate and the first nitride semiconductor layer to a second temperature, the second temperature being higher than the first temperature; and
forming a second nitride semiconductor layer including aluminum, on the first nitride semiconductor layer that is at the second temperature,
wherein in the forming of the first nitride semiconductor layer, a first V/III ratio to a supply amount of a Group V element to a supply amount of a Group III element is higher than a second V/III ratio to a supply amount of the Group V element to a supply amount of the Group III element in the forming of the second nitride semiconductor layer.

2. The method for manufacturing the nitride semiconductor substrate according to claim 1, wherein the first nitride semiconductor layer and the second nitride semiconductor layer are aluminum nitride layers.

3. The method for manufacturing the nitride semiconductor substrate according to claim 1,
wherein the first temperature is higher than or equal to 600° C. and less than 1,000° C., and
wherein the second temperature is higher than or equal to 1,000° C. and less than or equal to 1,200° C.

4. The method for manufacturing the nitride semiconductor substrate according to claim 1, wherein a difference between the second temperature and the first temperature is 100° C. or higher.

5. The method for manufacturing the nitride semiconductor substrate according to claim 1, wherein first pressure in a furnace obtained in the forming of the first nitride semiconductor layer is higher than second pressure in the furnace obtained in the forming of the second nitride semiconductor layer.

6. The method for manufacturing the nitride semiconductor substrate according to claim 1, wherein a total thickness of the first nitride semiconductor layer and the second nitride semiconductor layer is 50 nm or less.

7. The method for manufacturing the nitride semiconductor substrate according to claim 1, wherein the second nitride semiconductor layer is thicker than the first nitride semiconductor layer.

8. The method for manufacturing the nitride semiconductor substrate according to claim 1,
wherein the first nitride semiconductor layer has a thickness of greater than or equal to 3 nm and less than or equal to 20 nm, and
wherein the second nitride semiconductor layer has a thickness of greater than or equal to 5 nm and less than or equal to 30 nm.

9. The method for manufacturing the nitride semiconductor substrate according to claim 1, wherein the changing of the temperature of the substrate and the first nitride semiconductor layer to the second temperature includes
changing the temperature of the substrate and the first nitride semiconductor layer to a third temperature that is higher than the second temperature, and
changing the temperature of the substrate and the first nitride semiconductor layer from the third temperature to the second temperature.

10. The method for manufacturing the nitride semiconductor substrate according to claim 9, wherein the third temperature is higher than or equal to 1,100° C. and less than or equal to 1,300° C.

11. The method for manufacturing the nitride semiconductor substrate according to claim 1, further comprising:
after the changing of the temperature of the substrate and the first nitride semiconductor layer to the second temperature, and before the forming of the second nitride semiconductor layer,
maintaining the temperature of the substrate and the first nitride semiconductor layer at the second temperature, without forming the second nitride semiconductor layer.

12. The method for manufacturing the nitride semiconductor substrate according to claim 1, wherein the substrate is a silicon carbide substrate.
